(19) United States
(12) Patent Application Publication
(10) Pub. No.: US 2013/0015545 A1
(43) Pub. Date: Jan. 17, 2013

(54) SOLID-STATE IMAGING DEVICE, MANUFACTURING METHOD OF SOLID-STATE IMAGING DEVICE AND ELECTRONIC APPARATUS

(71) Applicants: Yoshinori Toumiya, Kumamoto (JP); Yoichi Ootsuka, Kumamoto (JP); Kensaku Maeda, Kanagawa (JP)

(72) Inventors: Yoshinori Toumiya, Kumamoto (JP); Yoichi Ootsuka, Kumamoto (JP); Kensaku Maeda, Kanagawa (JP)

(73) Assignee: SONY CORPORATION, Tokyo (JP)

(21) Appl. No.: 13/540,713

(22) Filed: Jul. 3, 2012

(30) Foreign Application Priority Data
Jul. 12, 2011 (JP) 2011-153913

(51) Int. Cl. H01L 31/0232

(52) U.S. Cl. 257/432; 438/69; 257/E31.127

(57) ABSTRACT

A solid-state imaging device includes: a substrate on which plural pixels having photoelectric converters are formed; an inorganic microlens made of an inorganic material and formed above the substrate, and an organic microlens made of an organic material and formed adjacent to the inorganic microlens so that a hem portion touches or overlaps a hem portion of the inorganic microlens.

### FIELD

The present disclosure relates to a solid-state imaging device, a manufacturing method of the solid-state imaging device and an electronic apparatus using the solid-state imaging device.

### BACKGROUND

A CCD-type solid-state imaging device and a CMOS-type solid-state imaging device are heretofore known as solid-state imaging devices used for a digital still camera or a digital video camera. In these solid-state imaging devices, a light receiving unit is formed in each of plural pixels formed in a two dimensional matrix state, and signal charges are generated in accordance with an amount of received light in the light receiving unit. The signal charges generated in the light receiving unit are transferred and amplified, thereby obtaining an image signal.

In the solid-state imaging device, a microlens is generally provided in each pixel for allowing incident light to be efficiently incident on the light receiving unit. Recently, a structure in which microlenses having different refractive indexes corresponding to respective pixels are formed is proposed according to specifications of the solid-state imaging device.

For example, in JP-A-2009-198547 (Patent Document 1), there is disclosed a structure in which microlenses having different refractive indexes corresponding to respective pixels of R (red), G (green) and B (blue) are formed to thereby improve light condensing efficiency. In the technique described in Patent Document 1, a pattern of microlenses having different heights according to pixels is formed above a transparent resin layer by applying a thermal reflow process twice, and dry etching is performed to thereby form the transparent resin layer to have a desired microlens shape.

In JP-A-2009-109965 (Patent Document 2), there is disclosed a structure in which the curvature of microlenses is changed in a phase detection pixel and an imaging pixel to thereby change the refractive index in a solid-state imaging device applying a pupil-division phase difference system for autofocus detection (AF). In the technique described in Patent Document 2, a plane shape of microlenses is formed to be a rectangular in the imaging pixel and to be a circular in the phase detection pixel, thereby obtaining microlenses having different curvatures.

A surface shape, a formed position and the like of microlenses are affected by light condensing efficiency and the refractive index, therefore, a method of forming microlenses having different refractive indexes more accurately is requested.

### SUMMARY

In view of the above, it is desirable to provide a solid-state imaging device in which microlenses having different refractive indexes are formed in respective pixels accurately. It is also desirable to provide an electronic apparatus using the solid-state imaging device.

An embodiment of the present disclosure is directed to a solid-state imaging device including a substrate on which plural pixels having photoelectric converters are formed, an inorganic microlens made of an inorganic material and formed above the substrate, and an organic microlens made of an organic material and formed adjacent to the inorganic microlens so that a hem portion touches or overlaps a hem portion of the inorganic microlens.

In the solid-state imaging device according to the embodiment of the present disclosure, the inorganic microlens is made of the inorganic material and the organic microlens is made of the organic material, thereby allowing the inorganic microlens and the organic microlens to have different refractive indexes.

Another embodiment of the present disclosure is directed to a manufacturing method of a solid-state imaging device including forming plural pixels having photoelectric converters on a substrate, forming an inorganic microlens made of an inorganic material above a given pixel formed on the substrate, and forming an organic microlens made of an organic material above a pixel in which the inorganic microlens is not formed.

In the manufacturing method according to the embodiment of the present disclosure, the inorganic microlens made of an inorganic material excellent in light resistance as well as heat resistance is formed first. Accordingly, the organic microlens can be formed without reducing lens performance of the inorganic microlens. As a result, it is possible to form microlenses having different refractive indexes accurately.

Still another embodiment of the present disclosure is directed to an electronic apparatus including an optical lens, a solid-state imaging device having a substrate on which plural pixels having photoelectric converters are formed, an inorganic microlens made of an inorganic material and formed above the substrate, and an organic microlens made of an organic material and formed adjacent to the inorganic microlens so that a hem portion touches or overlaps a hem portion of the inorganic microlens, on which light condensed on the optical lens is incident, and a signal processing circuit processing output signals outputted from the solid-state imaging device.

According to the embodiments of the present disclosure, the solid-state imaging device in which microlenses having different refractive indexes are accurately formed can be obtained. It is also possible to obtain an electronic apparatus in which image quality is improved by applying the solid-state imaging device.

### BRIEF DESCRIPTION OF THE DRAWINGS

FIG. 1 is a schematic structural view showing an entire CMOS-type solid-state imaging device according to a first embodiment of the present disclosure;

FIG. 2 is a cross-sectional structure of pixels of the solid-state imaging device according to the first embodiment of the present disclosure;

FIGS. 3A and 3B are process views (No. 1) showing a manufacturing method of the solid-state imaging device according to the first embodiment of the present disclosure;

FIGS. 4C and 4D are process views (No. 2) showing a manufacturing method of the solid-state imaging device according to the first embodiment of the present disclosure;

FIGS. 5E and 5F are process views (No. 3) showing a manufacturing method of the solid-state imaging device according to the first embodiment of the present disclosure;

FIGS. 6G and 6H are process views (No. 4) showing a manufacturing method of the solid-state imaging device according to the first embodiment of the present disclosure;

FIG. 7I is a process view (No. 5) showing a manufacturing method of the solid-state imaging device according to the first embodiment of the present disclosure;

FIG. 8 is a cross-sectional structure of pixels of the solid-state imaging device according to a second embodiment of the present disclosure;

FIGS. 9A and 9B are process views (No. 1) showing a manufacturing method of the solid-state imaging device according to the second embodiment of the present disclosure;

FIGS. 10C and 10D are process views (No. 2) showing a manufacturing method of the solid-state imaging device according to the second embodiment of the present disclosure;

FIGS. 11E and 11F are process views (No. 3) showing a manufacturing method of the solid-state imaging device according to the second embodiment of the present disclosure;

FIGS. 12G and 12H are process views (No. 4) showing a manufacturing method of the solid-state imaging device according to the second embodiment of the present disclosure;

FIGS. 13A to 13C are planar structural views corresponding to the manufacturing method of the solid-state imaging device according to the second embodiment of the present disclosure; and

FIG. 14 is a schematic structural view of an electronic apparatus according to a third embodiment of the present disclosure.

### DETAILED DESCRIPTION

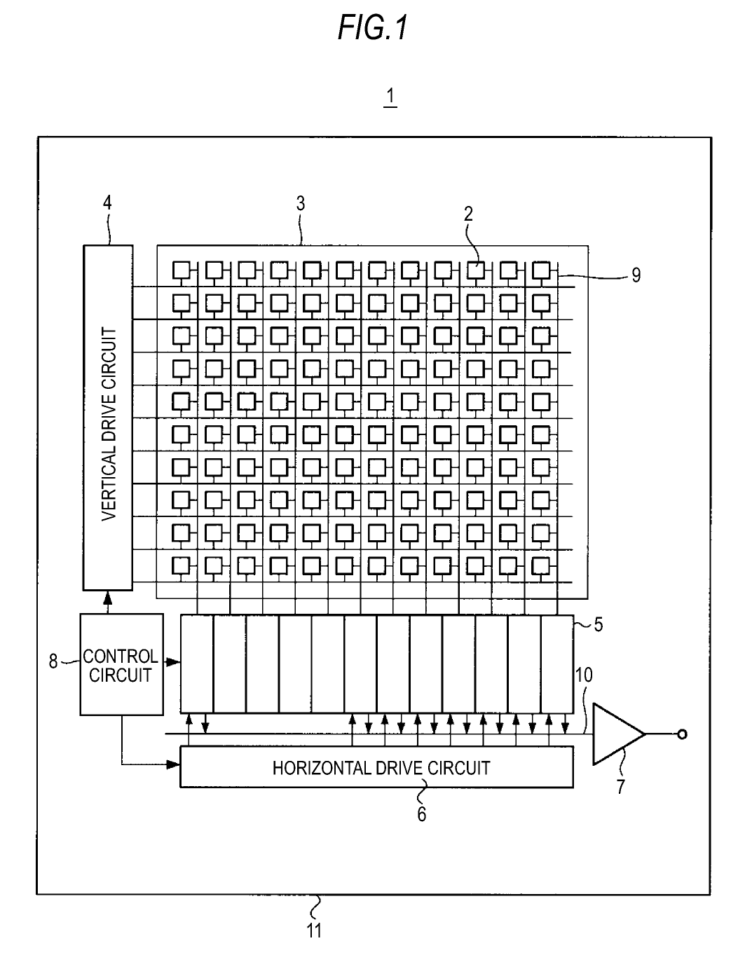

Hereinafter, examples of an electronic apparatus according to an embodiment of the present disclosure, a solid-state imaging device used for the electronic apparatus will be explained with reference to FIG. 1 to FIG. 10D. The embodiment of the present disclosure will be explained in the following order. The present disclosure is not limited to the following examples.

### 1. First Embodiment

### Solid-State Imaging Device

1-1 Entire Structure of Solid-State Imaging Device

1-2 Structure of Relevant Part of Solid-State Imaging Device

1-3 Manufacturing Method of Solid-State Imaging

Device

### 2. Second Embodiment

### Solid-State Imaging Device

2-1 Structure of Relevant Part of Solid-State Imaging Device

2-2 Manufacturing Method of Solid-State Imaging Device

### 3. Third Embodiment

### Electronic Apparatus

### <1. First Embodiment: Solid-State Imaging Device>

### [1-1 Entire Structure of Solid-State Imaging Device]

FIG. 1 is a schematic structural view showing an entire CMOS-type solid-state imaging device according to a first embodiment of the present disclosure.

A solid-state imaging device 1 according to the embodiment includes a pixel area 3 having plural pixels 2 arranged on a substrate 11 made of silicon, a vertical drive circuit 4, column signal processing circuits 5, a horizontal drive circuit 6, an output circuit 7, a control circuit 8 and so on.

Plural pixels 2 each have a photoelectric converter including a photodiode, and plural pixel transistors, which are regularly arranged on the substrate 11 in a two dimensional array. The pixel transistors may be four MOS transistors including a transfer transistor, a reset transistor, a selection transistor, an amplifier transistor or maybe three transistors including the above transistors other than the selection transistor.

The pixel area 3 includes the plural pixels 2 arranged regularly in the two dimensional array. The pixel area 3 has an effective pixel area in which light is actually received and signal charges generated by photoelectric conversion are amplified to be read to the column processing circuit 5 and a black-reference pixel area (not shown) for outputting optical black as a black level reference. The black-reference pixel area is normally formed at an outer peripheral portion of the effective pixel area.

The control circuit 8 generates clock signals, control signals and so on as operation references for the vertical drive circuit 4, the column signal processing circuits 5, the horizontal drive circuit 6 and the like based on a vertical synchronization signal, a horizontal synchronization signal and a master clock. The clock signals, the control signals and so on generated in the control circuit 8 are inputted into the vertical drive circuit 4, the column signal processing circuits 5, the horizontal drive circuit 6 and so on.

The vertical drive circuit 4 is formed by, for example, a shift register, selectively scanning respective pixels 2 in the pixel area 3 in units of rows sequentially in the vertical direction. Then, the vertical signal circuit 4 supplies pixel signals based on signal charges generated in accordance with an amount of received light in photodiodes of respective pixels 2 to the column signal processing circuits 5 through vertical signal lines.

The column signal processing circuits 5 are arranged with respect to respective columns of the pixels 2, performing signal processing such as noise reduction and signal amplification to signals outputted from pixels 2 of one row in units of pixel columns by using a signal from the black-reference pixel area (formed around the effective pixel area though not shown). Horizontal selection switches (not shown) are provided between the column signal processing circuits 5 and the horizontal signal line 10 at output stages of the column signal processing circuits 5.

The horizontal drive circuit 6 is formed by, for example, a shift register, sequentially selecting respective column signal processing circuits 5 by sequentially outputting a horizontal scanning pulse and allowing pixel signals to be outputted from respective column signal processing circuits 5 to the horizontal drive circuit 10.

The output circuit 7 performs signal processing to the signals sequentially supplied from respective column signal processing circuits 5 through the horizontal signal line 10 and outputs the signals.

### [1-2 Structure of Relevant Part of Solid-State Imaging Device]

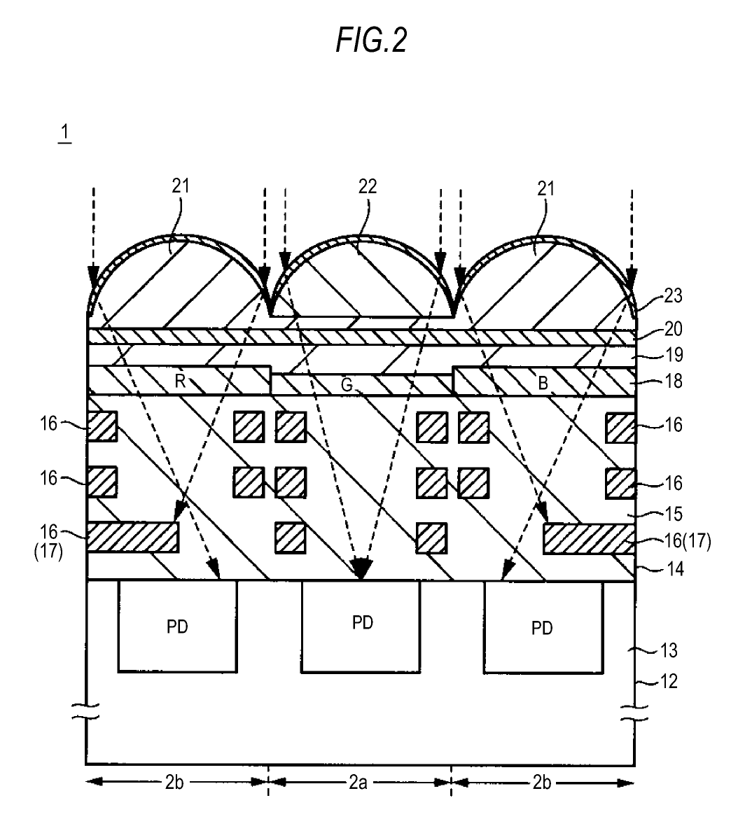

FIG. 2 shows a cross-sectional structure of a relevant part of the solid-state imaging device 1 according to the present embodiment. In FIG. 2, the cross-sectional structure of three pixels in the pixel area is shown. In the present embodiment, a solid-state imaging device having an autofocus function is cited as an example, in which the pixel area includes imaging pixels 2a for outputting pixel signals of an object image and phase difference detection pixels 2b for detecting a focus position. FIG. 2 shows a cross-section of an area formed so that the imaging pixel 2a is sandwiched by the phase difference detection pixels 2b. The imaging pixel 2a and the phase difference detection pixel 2b will be described later. In the following description, when it is not necessary to distinguish between the imaging pixel 2a and the phase difference detection pixel 2b, they will be explained as the pixels 2.

The solid-state imaging device 1 according to the embodiment includes a substrate 12 on which plural pixels 2 each having a photodiode PD as a photoelectric converter are formed, a wiring layer 14, color filter layers 18, a planarization layer 19 and a stress relaxation layer 20. The solid-state imaging device 1 further includes an inorganic microlens 21 formed above the phase difference detection pixel 2b and an organic microlens 22 formed above the imaging pixel 2a.

The substrate 12 is formed by a semiconductor substrate made of, for example, silicon. On a surface of the substrate 12, a first-conductive type, for example, a p-type semiconductor well region 13 is formed. The photodiode PD forming the photoelectric converter and pixel transistors (not shown) are formed in each pixel on the surface side of the semiconductor well 13.

The photodiode PD is formed by a second-conductive type, for example, an n-type impurity region, generating and accumulating signal charges according to the amount of incident light. The signal charges generated and accumulated in the photodiode PD are read out pixel by pixel through not-shown pixel transistors.

The wiring layer 14 is formed on the surface side of the substrate 12, including wiring 16 stacked in plural layers (three layers in FIG. 2) through an interlayer insulating film 15. The wiring 16 is formed so that the photodiode PD formed in the substrate 12 opens to the light incident side above the imaging pixel 2a. On the other hand, the wiring 16 in the bottom layer, namely, the wiring 16 on the closest side to the surface of the substrate 12 doubles as a light shielding film 17 which partially shields the phase difference detection pixel 2b from light above the phase difference detection pixel 2b. The wiring 16 above the light shielding film 17 is formed so that the photodiode PD formed on the substrate 12 opens to the light incident side in the same manner as the imaging pixel 2a.

Incidentally, the phase difference detection pixel 2b is a pixel outputting a phase difference detection signal for performing autofocus detection (AF). The autofocus function in the solid-state imaging device 1 according to the embodiment applies a pupil-division phase difference system obtaining two images by performing pupil division. Accordingly, light flux from a not-shown optical exit pupil provided on an upper portion of the solid-state imaging device 1 is separated by two phase difference detection pixels 2b and the phase difference between images outputted from the pair of phase difference detection pixels 2b is detected to thereby perform autofocus.

Additionally, the light shielding film 17 is formed for separating light flux from exit pupil regions in symmetrical positions. In the pair of phase difference detection pixels 2b, opening regions opened by the light shielding film 17 are provided in mirror symmetry.

The color filter layers 18 are formed over the wiring layer 14, which are made of a material selectively transmitting light of, for example, red (R), green (G) and blue (B) in respective pixels 2. The pixels 2 are formed by three primary colors of red (R), green (G) and blue (B) in FIG. 2, however, it is not limited to the example, and it is possible to use cyan, yellow and black, or white transmitting all light and not transmitting light in an infrared region. Additionally, it is possible to use the color filter layers 18 transmitting different colors according to pixels, or to use the color filter layers 18 transmitting the same color in all pixels 2. The combination of colors transmitted through the color filter layers 18 can be variously selected according to specifications. It is necessary to achieve optimum spectral characteristics according to filters for improving sensitivity characteristics as well as color reproducibility in the color filter layers 18, therefore, the thickness of respective filters differ according to the color.

The planarization layer 19 is formed on the color filter layers 18 for planarizing the color filter layers 18 having different thicknesses according to the color as described above. Materials having permeability, heat resistance and so on are preferably used for the planarization layer 19, for example, an acrylic thermosetting resin material, a styrene resin material, an epoxy resin material and so on can be used. Furthermore, when the vertical structure of layers is allowed to be lower for improving light condensing characteristics of the solid-state imaging device 1, it is preferable to use an acrylic resin material, a styrene resin material, an epoxy resin material and so on having both a thermoplastic property and a thermosetting property.

The stress relaxation layer 20 is formed on the planarization film 19 for relaxing the difference in film stress between the planarization film 19 made of the above-described organic material and the inorganic microlens 21 made of a later-described material. The stress relaxation layer 20 is preferably made of an inorganic material as well as preferably formed by using a deposition method of a low-temperature CVD (Chemical Vapor Deposition) process. It is preferable to use any of silicon compounds, for example, represented by composition formulas SiO₂ (hereinafter, SiO), Si₃N₄ (hereinafter SiN) or SiₓO_{y} (0<x≦1, 0<y≦1, hereinafter written as SiON) as the stress relaxation layer 20.

The inorganic microlens 21 is formed on the stress relaxation layer 20 above the phase difference detection pixel 2b so that the surface thereof has a desirable curvature. The inorganic microlens 21 formed above the phase difference detection pixel 2b is made of an inorganic material, and it is preferable to use any of, for example, SiN, SiO and SiON.

Additionally, it is preferable that the phase difference detection pixel 2b is formed so that the focus position of incident light will be on the surface of the light shielding film 17 for obtaining the pupil-divided image as the phase difference detection signal. Accordingly, the inorganic microlens 21 formed above the phase difference detection pixel 2b is preferably made of an inorganic material with a higher refractive index than an organic material making the later-described organic microlens 22, which is preferably made of, for example, SiN or SiON. The microlens 21 is formed to have a curvature in which a focal point of incident light is on the surface of the light shielding film 17.

The organic microlens 22 is formed over the planarization film 19 above the imaging pixel 2a so that the surface thereof has a desired curvature. The organic microlens 22 formed above the imaging pixel 2a is made of an organic material, and preferably made of, for example, an acrylic resin material, a styrene resin material, an epoxy resin material or acrylic/styrene copolymerization resin material. Additionally, it is preferable that the imaging pixel 2a is formed so that the focus position will be on the surface of the substrate 12 for improving sensitivity. Accordingly, the organic microlens 22 formed above the imaging pixel 2a is formed to have a curvature in which a focal point of incident light is on the surface of the substrate 12.

As described above, the inorganic microlens 21 made of the inorganic material is formed above the phase difference detection pixel 2b in which a focal length is set to be shorter than in the imaging pixel 2a in the present embodiment. On the other hand, the organic microlens 22 made of the organic material is formed above the imaging pixel 2a in which the focal length is set to be longer than in the phase difference detection pixel 2b.

An antireflection film 23 is formed so as to cover surfaces of the inorganic microlenses 21 and the organic microlenses 22, which is formed for reducing reflection of light on the surface of the microlenses. As materials for the antireflection film 23, for example, a LTO (Low Temperature Oxide) film, SiON and the like can be used.

Incidentally, the film stress largely differs between the organic material layer and the inorganic material layer. Therefore, when the inorganic microlens 21 made of the inorganic material is stacked on the planarization film 19 made of the organic material so as to directly touch the film, wrinkles or distortion due to the difference in film stress occurs in the interface. That is, when the inorganic material layer and the organic material layer are stacked, problems due to the difference in film stress occur in the interface of stacked layers.

In response to the above, in a stacked body of the planarization film 19 made of the organic material and the inorganic microlens 21 made of inorganic material, the stress relaxation layer 20 having a stress value between film stress values of the organic material layer and the inorganic material layer as well as different from these values is formed. That is, in the present embodiment, the relation of the film stress will be the organic material layer<the stress relaxation layer<the organic material layer. Materials satisfying the condition will be used for the stress relaxation layer 20.

As described above, it is possible to relax the difference in film stress between the planarization film 19 and the inorganic microlens 21 formed above and below the stress relaxation layer 20 by providing the stress relaxation layer 20. Accordingly, occurrence of problems on the surface due to the difference in film stress can be suppressed even when the organic material layer and the inorganic material layer are stacked. As a result, problems of surface wrinkles or distortion generated on the interface of stacked layers can be suppressed, and pattern formation can be performed without problems in a subsequent lithography process. Therefore, it is possible to avoid deterioration of light condensing characteristics in the solid-state imaging device 1.

Materials applicable to the planarization film 19, the stress relaxation layer 20 and the inorganic microlens 21 have been described as the above. It is preferable to combine the above materials so that the planarization film 19 is formed by using an acrylic thermoplastic cured material and the inorganic microlens 21 is formed by using a low-temperature SiN film. As the stress relaxation layer 20 is formed by using the low-temperature SiON film in this case, the stress relaxation layer 20 (SiON) and an inorganic microlens layer 21a (SiN) can be formed continuously in the same CVD process without adding a new process, which simplifies the process.

As optical characteristics of the stress relaxation layer 20, it is preferable that the stress relaxation layer 20 has transparency with the refractive index of 1.4 to 2.0. Particularly, when the stress relaxation layer 20 is made of SiON, the refractive index is 1.6 to 1.9. Accordingly, the stress relaxation layer 20 can double as an antireflection film for reducing interface reflection between the inorganic microlens 21 made of SiN with the refractive index of 1.8 to 2.0 and the planarization film 19 made of an acrylic resin with the refractive index of 1.4 to 1.5. As a result, light condensing characteristics of the solid-state imaging device 1 is improved.

The film stress of the stress relaxation layer 20 is preferably −100 to 100 MPa. The film stress values shown here were measured by using a thin-film stress measuring apparatus (wafer-warpage measurement apparatus FSM 500TC (VISION, INC).

In the solid-state imaging device 1 having the above structure, signal charges corresponding to the amount of incident light are generated in the imaging pixels 2a to be outputted as pixel signals to thereby obtain an image. In the phase difference detection pixels 2b, pupil-divided images are obtained and the phase difference is detected, thereby performing autofocus. Plural pairs of phase difference detection pixels 2b which separate the light flux from exit pupil regions in symmetrical positions are provided in the pixel area 3 according to specifications of the solid-state imaging device. The phase difference detection pixels 2b can be provided in lines or can be arranged at random. Though the red pixel and the blue pixel are phase difference detection pixels 2b and the green pixel is the imaging pixel 2a in FIG. 2, pixels forming the phase difference detection pixels 2b can be arbitrarily set.

In the solid-state imaging device 1 according to the embodiment, the inorganic microlens 21 is formed by using an inorganic material with a higher refractive index than an organic material forming the organic microlens 22 and is formed to have a curvature so that the focal point of incident light will be the surface of the light shielding film 17. Accordingly, light flux of an object transmitted through one region of a pair of partial regions of an imaging optical system (not shown) set on the light incident surface side of the solid-state imaging device 1 is incident on one of the pair of phase difference detection pixels 2b. On the other hand, light flux of the object transmitted through the other region of the pair of partial regions of the imaging optical system set on the light incident surface side of the solid-state imaging device 1 is incident on the other phase difference detection pixel 2b.

As described above, the light shielding film 17 is provided and the refractive index of the inorganic microlens 21 is adjusted so that a focal position of incident light is on the light shielding film 17 in the phase difference detection pixels 2b, therefore, desired light flux obtained by pupil division is incident on respective phase difference detection pixels 2b. Then, the phase difference can be detected by detecting the phase difference between images detected by the pair of phase difference detection pixels 2b.

### [1-3 Manufacturing Method of Solid-State Imaging Device]

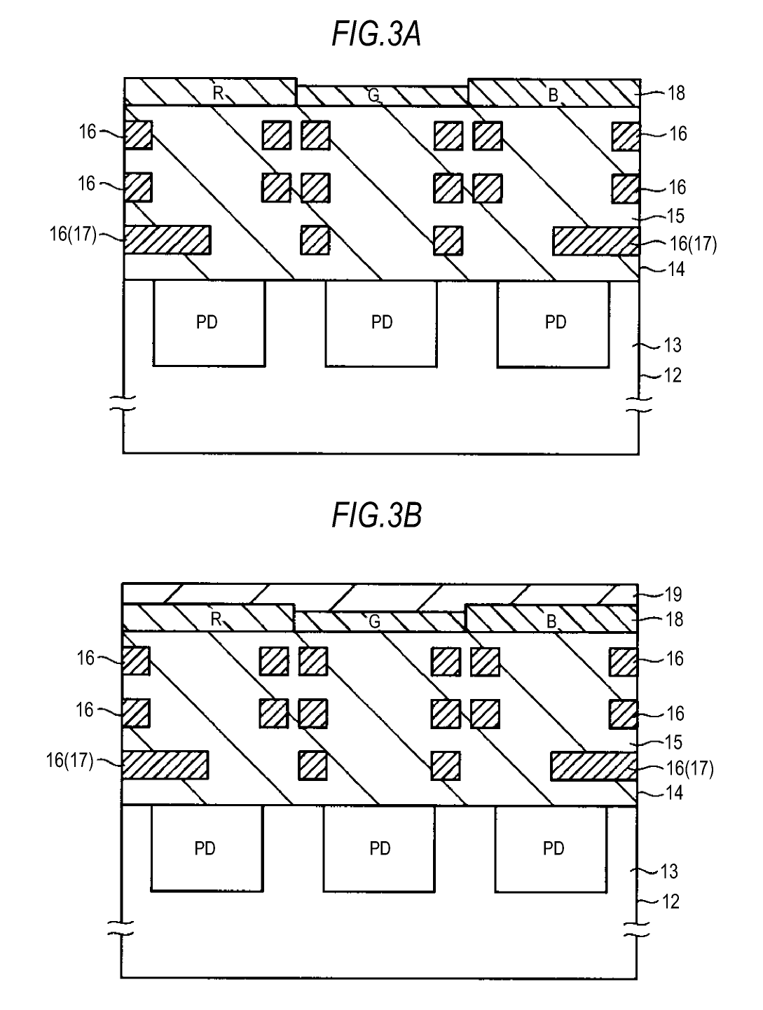

Next, a manufacturing method of the solid-state imaging device 1 according to the embodiment will be explained. FIGS. 3A, 3B to FIG. 7I are manufacturing process views showing a manufacturing method of the solid-state imaging device 1 according to the embodiment.

First, as shown in FIG. 3A, the p-type semiconductor well region 13 is formed on the surface side of the substrate 12 made of silicon and the photodiodes PD are formed on the surface of the region by ion implantation. Subsequently, after not-shown pixel transistors are formed, the interlayer insulating film 15 and the wiring 16 are formed repeatedly, thereby forming the wiring layer 14 including plural layers (three layers in the embodiment) of wiring 16. Then, the color filter layers 18 are pattern-formed according to the color above the wiring layer 14, thereby forming the color filter layers 18 which are different according to the pixels 2. The same manufacturing method as a common solid-state imaging device can be applied to the above processes.

Next, as shown in FIG. 3B, the planarization film 19 made of an organic resin material, particularly, an acrylic resin material, a styrene resin material or an epoxy resin material is formed over the color filter layers 18. In order to planarize the planarization film 19 to be thin, it is preferable to use a resin material having both a thermosetting property and thermoplastic property. The planarization film 19 is formed by applying the above material over the color filter layer 18 by a spin coating process and by performing thermoset processing for several minutes at a temperature at which heat resistance deterioration of the color filter layers 18 and the like does not occur, for example, at 200 to 300 degrees. As the planarization film 19 is formed, convexo-concave surfaces of the color filter layers 18 are planarized.

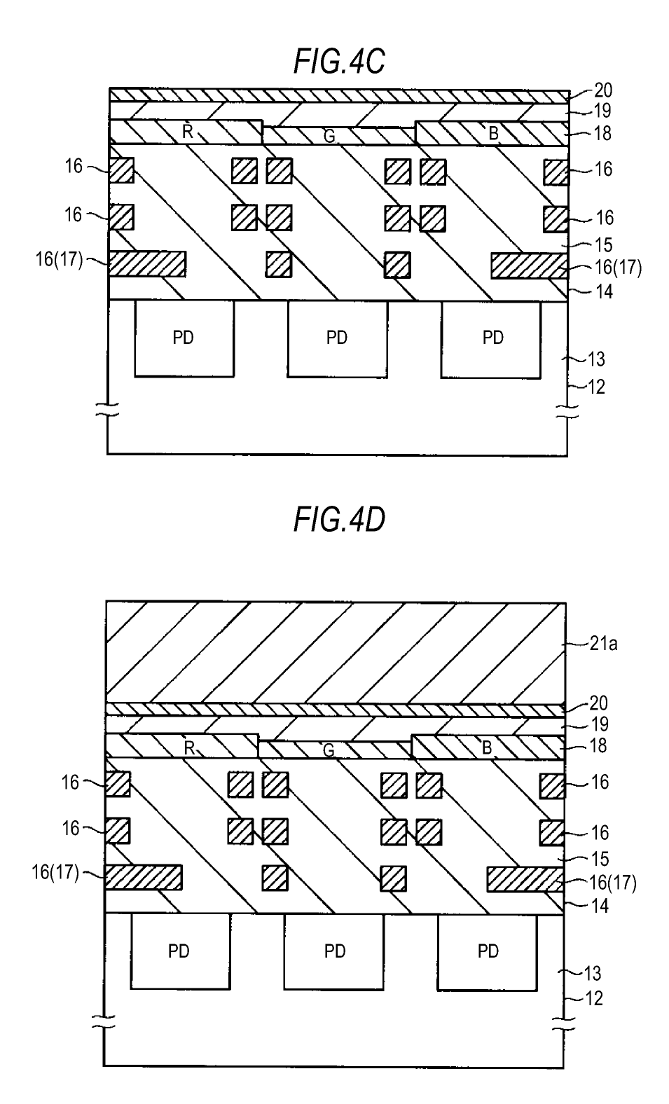

Next, as shown in FIG. 4C, the stress relaxation layer 20 is formed over the planarization film 19. The stress relaxation layer 20 is formed by processing SiN, SiO, SiON and the like by using, for example, a plasma CVD process at a processing temperature of 200 to 230 degrees in the same manner as described above.

Next, as shown in FIG. 4D, the inorganic microlens layer 21a for forming the inorganic microlens 21 is formed over the stress relaxation layer 20. The inorganic microlens layer 21a is formed by processing an inorganic material such as SiN by using, for example, the plasma CVD process at a processing temperature of 200 to 230 degrees.

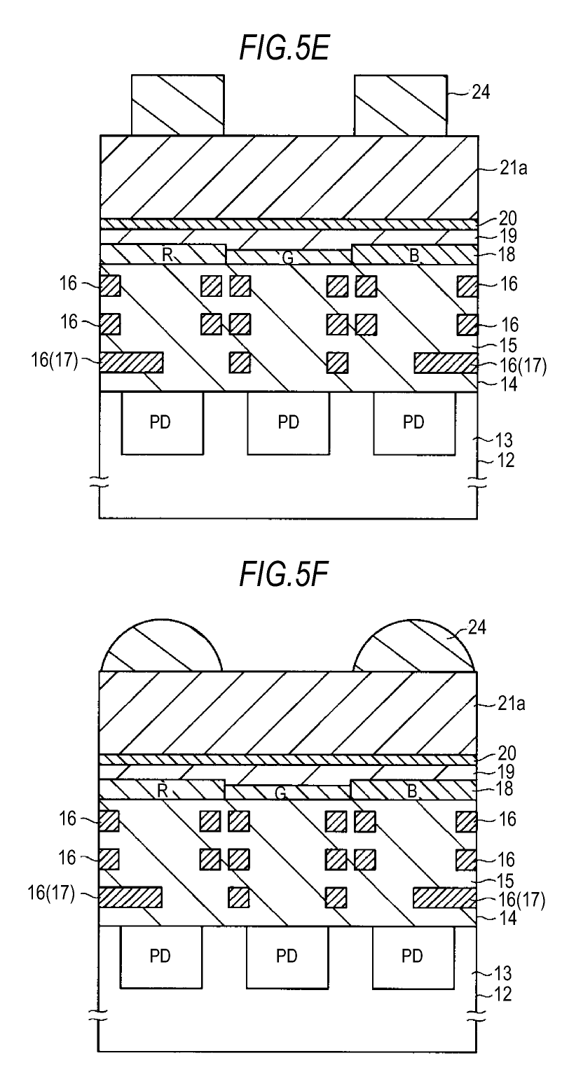

Next, as shown in FIG. 5E, a resist mask 24 opening at desired regions is formed over the inorganic microlens layer 21a. The resist mask 24 is formed by applying a resist layer and patterning the layer by photolithography. In the present embodiment, the resist mask is formed so that portions above the imaging pixels 2a are opened.

Next, as shown in FIG. 5F, thermal reflow is performed to the resist mask 24 to form the resist mask 24 to have a lens shape. Also in this case, processing is performed at a processing temperature not deteriorating lower layers.

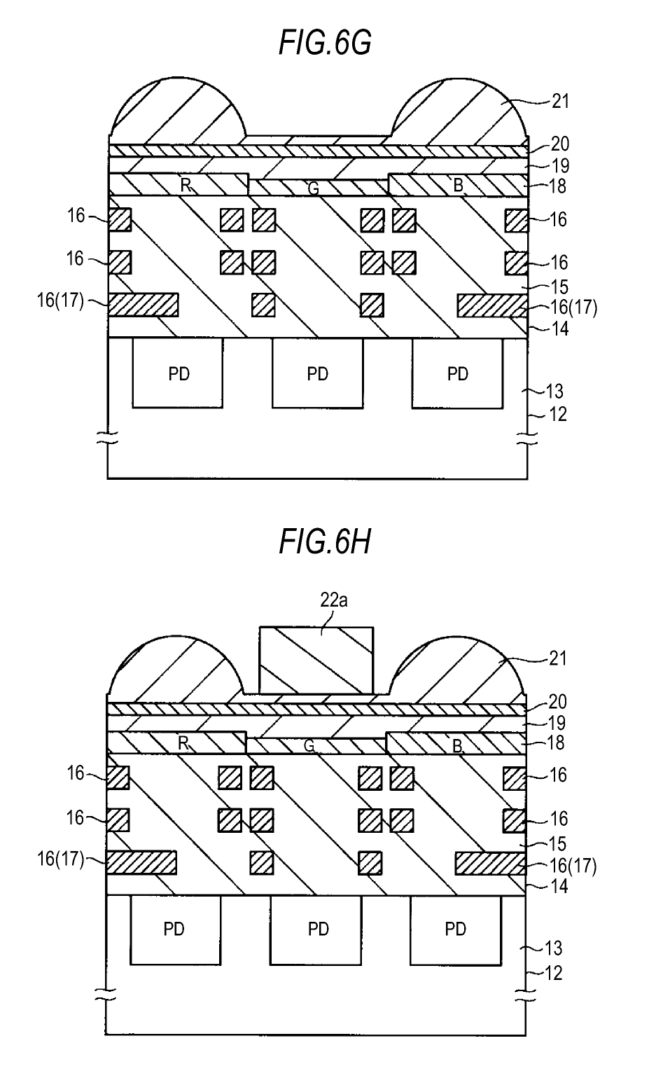

Next, an etching process is performed through the resist mask 24, thereby transferring the shape of the resist mask 24 onto the inorganic microlens layer 21a to form the organic microlenses 21 having a hemispherical shape as shown in FIG. 6G. The etching of the inorganic material layer such a SiN forming the inorganic microlenses 21 is performed by a plasma etching process using, for example, CF₄/O₂ gas. Though the etching is performed so that a layer of the inorganic microlens layer 21a remains on the whole surface in FIG. 6G, it is also possible to perform etching so that the inorganic microlens layer 21a does not remain on regions other than regions on which the inorganic microlenses 21 are formed.

Next, as shown in FIG. 6H, an organic microlens layer 22a made of an organic material is formed above the pixel 2 on which the inorganic microlens 21 is not formed, namely, the imaging pixel 2a in the present embodiment. The organic microlens layer 22a is formed by applying an organic material layer on the whole surface of the pixel area 3 and by patterning the layer in the same manner as a common method.

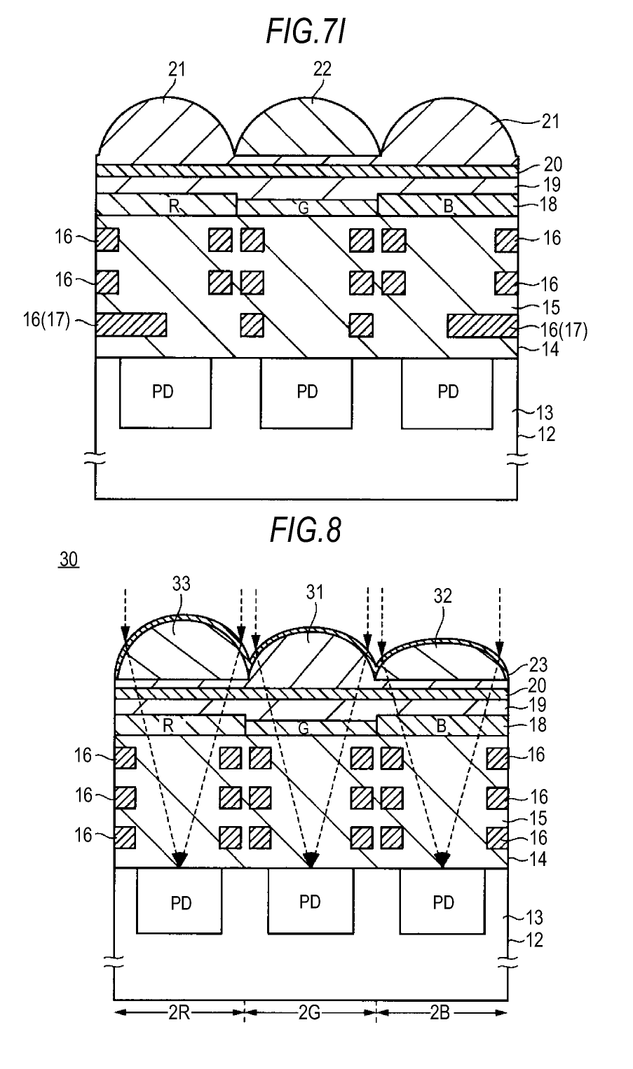

Next, thermal reflow is performed to the organic microlens layer 22a to thereby form the organic microlens 22 having the hemispherical shape as shown in FIG. 7I. After that, the antireflection film 23 made of LTO or SiOC is formed on surfaces of the inorganic microlenses 21 and the organic microlenses 22 to complete the solid-state imaging device 1 shown in FIG. 2.

In the embodiment, the inorganic microlens 21 is made of an inorganic material excellent in heat resistance as well as light resistance. Accordingly, it is possible to form the organic microlens 22 without causing damages on the shape or the surface of the inorganic microlens 21. Therefore, lenses having different refractive indexes can be easily formed. As the inorganic microlens 21 is made of an inorganic material, the range of temperature setting for reflow can be expanded at the time of creating the organic microlens 22 made of an organic material.

When the inorganic microlenses 21 are formed so as to sandwich the organic microlens 22 made of an organic material as shown in FIG. 2, the slip of the organic material stops at hems of the inorganic microlenses 21 at the time of reflow of the organic microlens layer 22a. Accordingly, slip characteristics at the time of reflow of the organic microlens layer 22a are relaxed and controllability in shape of the organic microlenses 22 is improved.

As described above, microlenses having different refractive indexes which are optimum respectively for the imaging pixel 2a and the phase difference detection pixel 2b can be formed, in which the optimum refractive index differs. The organic microlens 22 made of an organic material is formed after forming the inorganic microlens 21 made of an inorganic material, thereby forming two types of microlenses having different refractive indexes without impairing lens performance.

Though the example in which the phase difference detection pixels 2b for autofocus are formed at desired regions has been described in the embodiment, it is also preferable that the pixels are provided in a checkered pattern. When the pixels are provided in the checkered pattern, four sides of an area in which the organic microlens 22 is formed is surrounded by the inorganic microlenses 21, therefore, the slip of resin stops at hems of the microlenses made of the inorganic material when the reflow of the organic material is performed. As a result, the microlens made of the organic material can be accurately formed.

### <2. Second Embodiment: Solid-State Imaging Device>

### [2-1 Structure of Relevant Part of Solid-State Imaging Device]

Next, a solid-state imaging device according to a second embodiment of the present disclosure will be explained. FIG. 8 shows a cross-sectional structure of a relevant part of a solid-state imaging device 30 according to the embodiment. As the entire structure of the solid-state imaging device 30 according to the embodiment is the same as the one of FIG. 1, the structure is not shown and repeated explanation is omitted. The same numerals are given to portions corresponding to those in FIG. 2 and repeated explanation is omitted in FIG. 8.

The solid-state imaging device 30 according to the embodiment is an example in which the pixels 2 are in Bayer arrangement of red (R), green (G) and blue (B), and microlenses having different refractive indexes are formed according to the color of respective pixels 2. In the present embodiment, an inorganic microlens 31 is formed in a green pixel 2G, a first organic microlens 32 is formed in a blue pixel 2B and a second organic microlens 33 is formed in a red pixel 2R. The longer a light wavelength is, the smaller refractive index is. Accordingly, the size relation among a refractive index “n1” of the inorganic microlens 31, a refractive index “n2” of the first organic microlens 32 and a refractive index “n3” of the second organic microlens 33 is set to n1>n2>n3, thereby making adjustment so that focal positions of light incident on respective pixels are on the surface of the substrate 12.

### [2-2 Manufacturing Method of Solid-State Imaging Device]

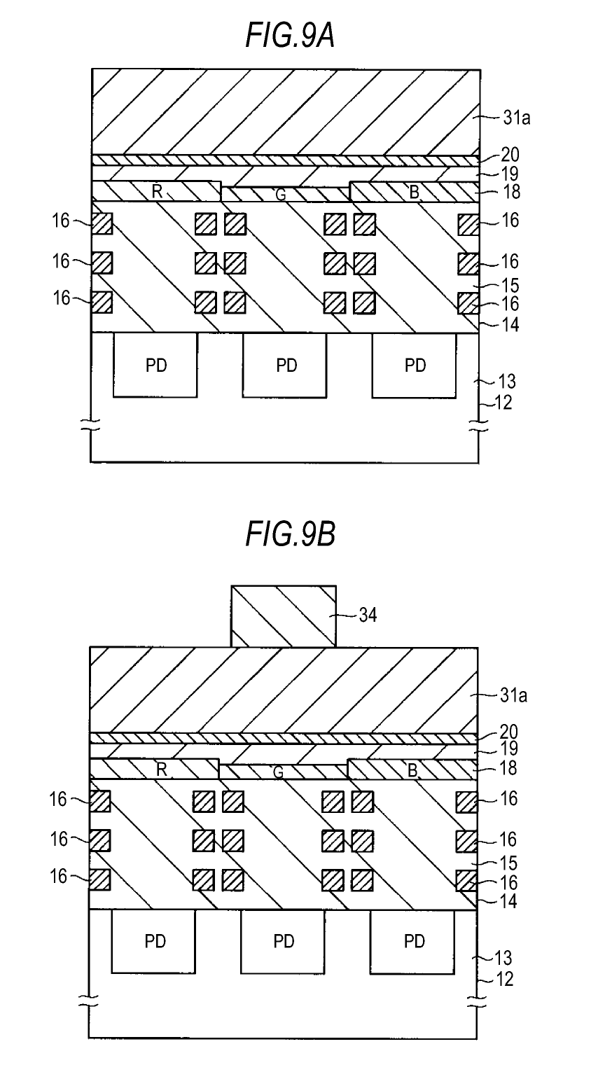

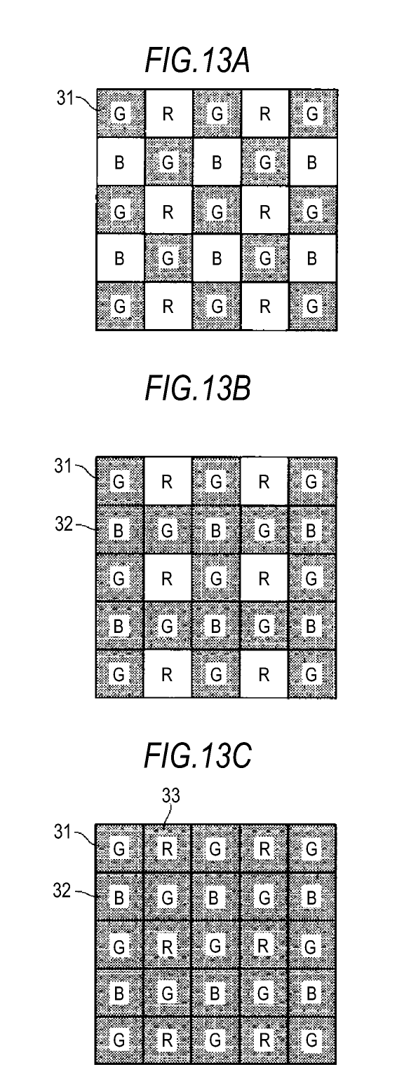

FIGS. 9A, 9B to FIG. 12G, 12H are cross-sectional views showing manufacturing processes of the solid-state imaging device 30 according to the embodiment. FIG. 13A to 13C show plan views corresponding to manufacturing processes of the solid-state imaging device 30 according to the embodiment.

First, the wiring layer 14, the color filter layers 18, the planarization layer 19 and the stress relaxation layer 20 are formed over the substrate 12 on which the pixels 2 are formed in the same manner as FIG. 3A to FIG. 4C.

Next, as shown in FIG. 9A, an inorganic microlens layer 31a for forming the inorganic microlens 31 is formed on the whole surface of the pixel area over the stress relaxation layer 20. The inorganic microlens layer 31a is formed by processing an organic material such as SiN by using, for example, the plasma CVD method at a processing temperature of 200 to 230 degrees.

Next, as shown in FIG. 9B, a resist mask 34 opening at regions other than the green pixel 2G is formed over the inorganic microlens layer 31a. The resist mask 34 is formed by applying a resist layer and patterning the layer by photolithography.

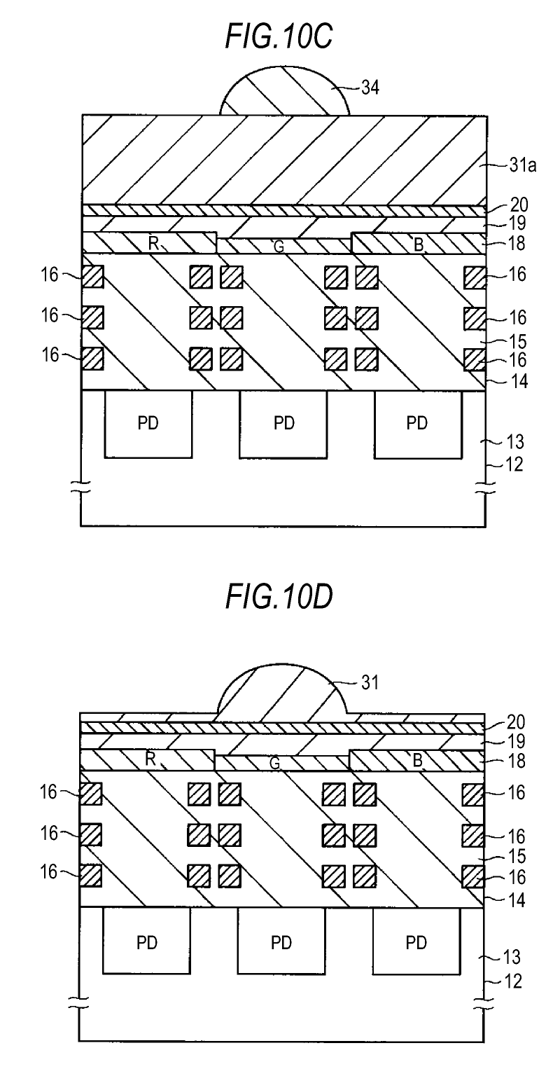

Next, as shown in FIG. 10C, thermal reflow is performed to the resist mask 34 to form the resist mask 34 to have a lens shape. Also in this case, processing is performed at a processing temperature not deteriorating lower layers.

Next, as shown in FIG. 10D, an etching process is performed through the resist mask 34, thereby transferring the shape of the resist mask 34 onto the inorganic microlens layer 31a to form the inorganic microlens 31 having the hemispherical shape. The etching of the inorganic material layer such a SiN forming the inorganic microlens 31 is performed by the plasma etching process using, for example, CF₄/O₂ gas.

As described above, the inorganic microlenses 31 made of the inorganic material are selectively formed above the green pixels 2G. FIG. 13A shows a planar structural view in the case where the inorganic microlenses 31 are formed above the green pixels 2G. In the embodiment, as the pixels 2 are in Bayer arrangement, the inorganic microlenses 31 are formed in the pixel area 3 in a checkered pattern as shown in FIG. 13A.

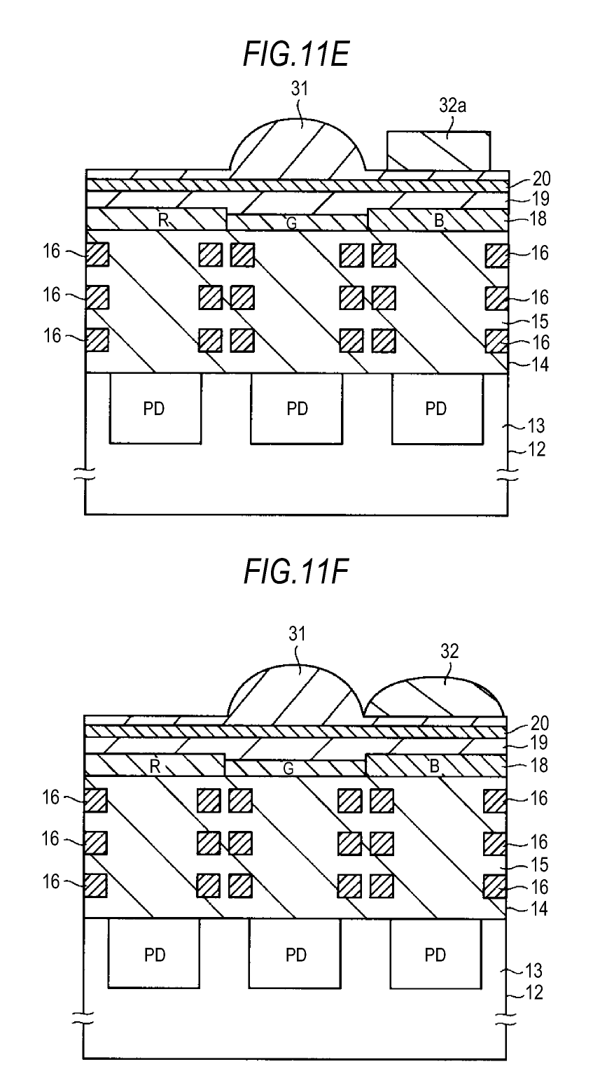

Next, as shown in FIG. 11E, a first organic microlens layer 32a made of an organic material is formed above the blue pixel 2B. The first organic microlens layer 32a is formed by applying an organic material layer on the whole surface of the pixel area and by patterning the layer in the same manner as a common method.

Next, as shown in FIG. 11F, thermal reflow is performed to the first organic microlens layer 32a to thereby form the first organic microlens 32 having the hemispherical shape. The first organic microlens 32 is formed to have a curvature in which the focal position of incident light is on the surface of the substrate 12.

FIG. 13B shows a planar structural view in the case where the first organic microlenses 32 are formed above the blue pixels 2B. In the embodiment, as the pixels 2 are in Bayer arrangement, the first organic microlenses 32 are formed at positions surrounded by the inorganic microlenses 31 formed in the checkered pattern. Accordingly, the slip of the organic material forming the first organic microlens layer 32a stops at hems of the inorganic microlenses at the time of reflow of the first organic microlens layer 32a. As a result, slip characteristics at the time of reflow of the first organic microlens layer 32a are relaxed and controllability in shape of first organic microlenses 32 is improved. Additionally, as the first organic microlens 32 are formed at regions surrounded by the inorganic microlenses 31, the first organic microlenses 32 are substantially formed in self-alignment.

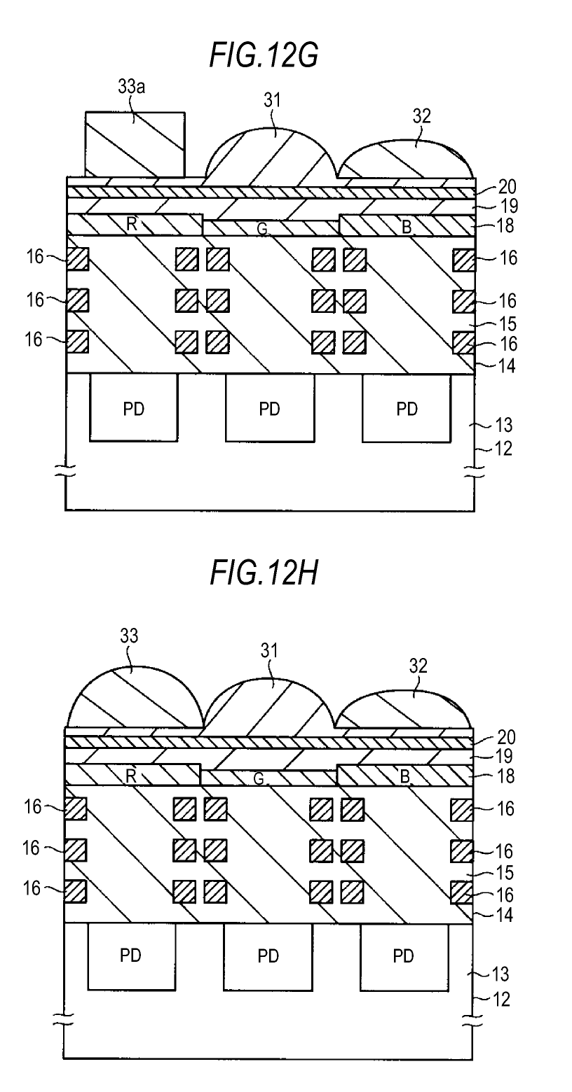

Next, as shown in FIG. 12G, a second organic microlens layer 33a made of an organic material is formed above the red pixel 2R. The second organic microlens layer 33a is formed by applying an organic material layer on the whole surface of the pixel area and by patterning the layer in the same manner as a common method.

Next, as shown in FIG. 12H, thermal reflow is performed to the second organic microlens layer 33a to thereby form the second organic microlens 33 having the hemispherical shape. The second organic microlens 33 is formed to have a curvature in which the focal position of incident light is on the surface of the substrate 12.

FIG. 13C shows a planar structural view in the case where the second organic microlenses 33 are formed above the red pixels 2R. In the embodiment, as the pixels 2 are in Bayer arrangement, the second organic microlenses 33 are formed at positions surrounded by the inorganic microlenses 31 formed in the checkered pattern. Accordingly, the slip of the organic material forming the second organic microlens layer 33a in a plane direction stops at hems of the inorganic microlenses 31 at the time of reflow of the second organic microlens layer 33a. As a result, slip characteristics at the time of reflow of the second organic microlens layer 33a are relaxed and controllability in shape of second organic microlenses 33 is improved. Additionally, as the second organic microlenses 33 are formed at the region surrounded by the inorganic microlenses 31, the second organic microlenses 33 are substantially formed in self-alignment.

After that, as shown in FIG. 8, the antireflection film 23 made of LTO or SiOC is formed on surfaces of the inorganic microlenses 31, the first organic microlenses 32 and the second organic microlenses 33 to complete the solid-state imaging device 30 according to the present embodiment.

Though the solid-state imaging device 30 according to the embodiment has the structure in which the first organic microlens 32 and the second organic microlens 33 stop at the hem of the inorganic microlens 31, it is possible to perform reflow until the organic microlenses partially overlap the hem of the inorganic microlens 31. The shapes of the first organic microlens 32 and the second organic microlens 33 can be controlled at the time of reflow, therefore, various selection is possible.

As described above, the microlenses made of an inorganic material are formed in the checkered pattern first, then, the microlenses made of an organic material are formed at regions where the microlenses are not formed in the present embodiment. Accordingly, when the microlenses made of the organic material are formed, the microlenses made of the inorganic material are already formed around thereof. Accordingly, as the slip of the microlenses made of the organic material is suppressed by the microlenses made of the inorganic material, slip characteristics are relaxed and the controllability as well as the degree of freedom in shape are improved. As a result, lenses with desired refractive indexes can be easily formed. As the organic microlenses are formed at regions in which four sides are surrounded by the inorganic microlenses, the organic microlenses are formed in self alignment at the time of reflow.

The same advantages as the first embodiment can be also obtained.

The example in which the first organic microlens 32 and the second organic microlens 33 are formed after the inorganic microlens 31 is formed has been explained in the above embodiment, however, it is not limited to the example. It is also possible to form an inorganic microlens at a given position, after that, to form an inorganic microlens with a different refractive index at a different position, then, to form an organic microlens lastly.

The examples of the CMOS-type solid-state imaging device has been explained in the solid-state imaging devices according to the first and second embodiments, however, the present disclosure can be also applied to a CCD-type solid-state imaging device.

The present disclosure can be also applied to a solid-state imaging device which detects distribution of the incident amount of infrared light, X-ray or particles to image the distribution as an image, not limited to the solid-state imaging device which detects distribution of the incident amount of visible light to image the distribution as an image. In the broad sense, the present disclosure can be applied to the entire solid-state imaging devices (physical value distribution detector) such as a fingerprint detection sensor which detect distribution of other physical values such as pressure or capacitance to image the distribution as an image.

Furthermore, the present disclosure is not limited to the solid-state imaging device which sequentially scans respective unit pixels in the pixel area in units of rows and reads pixel signals from respective unit pixels. The present disclosure can be applied to an X-Y address type solid-state imaging device which selects arbitrary pixels in units of pixels and reads signals from the selected pixels in units of pixels.

The solid-state imaging device can be formed in a form of one-chip as well as in a module state having an imaging function in which the pixel area and a signal processing unit or an optical system are integrally packaged.

The present disclosure is not limited to the application to the solid-state imaging device but can be also applied to the imaging apparatuses. Here, the imaging apparatuses mean camera systems such as a digital still camera and a digital video camera, or electronic apparatuses having the imaging function such as a cellular phone device. The form of the module state mounted on the electronic apparatus, namely, a camera module may be called an imaging apparatus.

### <3. Third Embodiment: Electronic Apparatus>

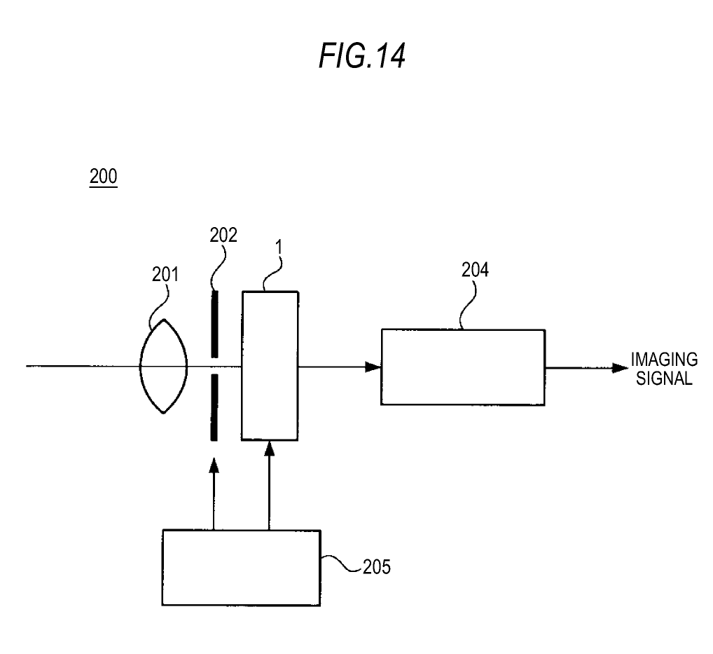

Next, an electronic apparatus according to a third embodiment of the present disclosure will be explained. FIG. 14 is a schematic structural view of an electronic apparatus 200 according to a third embodiment of the present disclosure.

The electronic apparatus 200 according to the present embodiment includes a solid-state imaging device 1, an optical lens 201, a shutter device 202, a drive circuit 205 and a signal processing circuit 204. The electronic apparatus 200 according to the embodiment shows an embodiment in the case where the solid-state imaging device according to the first embodiment of the present disclosure described as the solid-state imaging device 1 is used for the electronic apparatus (camera).

The optical lens 201 forms image light (incident light) from an object on an imaging surface of the solid-state imaging device 1. Accordingly, signal charges are accumulated in the solid-state imaging device 1 in a fixed period of time. The shutter device 202 controls light irradiation period and a light shielding period with respect to the solid-state imaging device 1. The drive circuit 205 supplies drive signals controlling a transfer operation of the solid-state imaging device 1 and a shutter operation of the shutter device 202. The signal transfer of the solid-state imaging device 1 is performed by a drive signal (timing signal) supplied from the drive circuit 205. The signal processing circuit 204 performs various signal processing. A video signal to which signal processing is performed is stored in a storage medium such as a memory or outputted to a monitor.

In the electronic apparatus 200 according to the embodiment, lens characteristics of on-chip microlenses are improved and light condensing characteristics are improved in the solid-state imaging device 1, which improves image quality.

As the electronic apparatus 200 to which the solid-state imaging device 1 can be applied is not limited to the camera. The solid-state imaging device 1 can be applied to imaging apparatuses including a digital still camera and camera modules for mobile devices such as a cellular phone device.

The configuration in which the solid-state imaging device 1 according to the first embodiment is used for the electronic apparatus as the solid-state imaging device 1 has been explained in the embodiment, however, the solid-state imaging device manufactured according to the second embodiment can be also used.

The present disclosure may be implemented as the following configurations.

(1) A solid-state imaging device including a substrate on which plural pixels having photoelectric converters are formed,

an inorganic microlens made of an inorganic material and formed above the substrate, and

an organic microlens made of an organic material and formed adjacent to the inorganic microlens so that a hem portion touches or overlaps a hem portion of the inorganic microlens.

(2) The solid-state imaging device described in the above (1), further including

a planarization film made of an organic material and formed on the substrate, and

a stress relaxation layer of at least one layer or more between the planarization film and the inorganic microlens.

(3) The solid-state imaging device described in the above (1) or (2),

in which the inorganic microlens is made of any of Si₃N₄, SiO₂ and SiON (0<X≦1, 0<Y≦1).

(4) The solid-state imaging device described in any of the above (1) to (3),

in which the stress relaxation layer is made of at least one or more materials selected from silicon compounds represented by Si₃N₄, SiO₂ and SiON (0<X≦1, 0<Y≦1).

(5) The solid-state imaging device described in any of the above (1) to (4),

in which a refractive index of the stress relaxation layer is 1.4 to 2.0.

(6) The solid-state imaging device described in any of the above (1) to (5),

in which the stress relaxation layer doubles as an antireflection film.

(7) The solid-state imaging device described in any of the above (1) to (6),

in which the inorganic microlenses are formed above a pair of phase difference detection pixels detecting pupil-divided images and outputting phase difference detection signals,

the organic microlens is formed above an imaging pixel outputting an image signal of an object, and

a refractive index of the inorganic microlenses is higher than a refractive index of the organic microlens.

(8) A manufacturing method of a solid-state imaging device including

forming plural pixels having photoelectric converters on a substrate,

forming an inorganic microlens made of an inorganic material above a given pixel formed on the substrate, and

forming an organic microlens made of an organic material above a pixel in which the inorganic microlens is not formed.

(9) The manufacturing method of the solid-state imaging device described in the above (8),

in which the process of forming the organic microlens includes

forming an organic microlens layer made of an organic material above a given pixel by patterning and

deforming the organic microlens layer by thermal reflow.

(10) The manufacturing method of the solid-state imaging device described in the above (8) or (9),

in which the inorganic microlenses are formed in a checkered pattern.

(11) The manufacturing method of the solid-state imaging device described in any of the above (8) to (10), further including

forming a planarization film made of an organic material on the substrate, and

forming a stress relaxation layer at least one layer or more on the planarization film before the process of forming the inorganic microlens.

(12) The manufacturing method of the solid-state imaging device described in any of the above (8) to (11),

in which the inorganic microlens is made of any of Si₃N₄, SiO₂ and SiON (0<X≦1, 0<Y≦1).

(13) The manufacturing method of the solid-state imaging device described in any of the above (8) to (12),

in which the stress relaxation layer is made of at least one or more materials selected from silicon compounds represented by Si₃N₄, SiO₂ and SiON (0<X≦1, 0<Y≦1).

(14) The manufacturing method of the solid-state imaging device described in any of the above (8) to (13),

in which a refractive index of the stress relaxation layer is 1.4 to 2.0.

(15) The manufacturing method of the solid-state imaging device described in any of the above (8) to (14),

in which organic microlenses having different refractive indexes are formed by repeating the formation of the organic microlenses.

(16) An electronic apparatus including

an optical lens,

a solid-state imaging device having

a substrate on which plural pixels having photoelectric converters are formed,

an inorganic microlens made of an inorganic material and formed above the substrate, and

an organic microlens made of an organic material and formed adjacent to the inorganic microlens so that a hem portion touches or overlaps a hem portion of the inorganic microlens, on which light condensed on the optical lens is incident, and

a signal processing circuit processing output signals outputted from the solid-state imaging device.

The present disclosure contains subject matter related to that disclosed in Japanese Priority Patent Application JP 2011-153913 filed in the Japan Patent Office on Jul. 12, 2011, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A solid-state imaging device comprising:
a substrate on which plural pixels having photoelectric converters are formed;
an inorganic microlens made of an inorganic material and formed above the substrate, and
an organic microlens made of an organic material and formed adjacent to the inorganic microlens so that a hem portion touches or overlaps a hem portion of the inorganic microlens.

2. The solid-state imaging device according to claim 1, further comprising:
a planarization film made of an organic material and formed on the substrate; and
a stress relaxation layer of at least one layer or more between the planarization film and the inorganic microlens.

3. The solid-state imaging device according to claim 2,
wherein the inorganic microlens is made of any of Si₃N₄, SiO₂ and SiON (0<X≦1, 0<Y≦1).

4. The solid-state imaging device according to claim 3,
wherein the stress relaxation layer is made of at least one or more materials selected from silicon compounds represented by Si₃N₄, SiO₂ and SiON (0<X≦1, 0<Y≦1).

5. The solid-state imaging device according to claim 4,
wherein a refractive index of the stress relaxation layer is 1.4 to 2.0.

6. The solid-state imaging device according to claim 5,
wherein the stress relaxation layer doubles as an antireflection film.

7. The solid-state imaging device according to claim 1,
wherein the inorganic microlenses are formed above a pair of phase difference detection pixels detecting pupil-divided images and outputting phase difference detection signals,
the organic microlens is formed above an imaging pixel outputting an image signal of an object, and
a refractive index of the inorganic microlenses is higher than a refractive index of the organic microlens.

8. A manufacturing method of a solid-state imaging device comprising:
forming plural pixels having photoelectric converters on a substrate;
forming an inorganic microlens made of an inorganic material above a given pixel formed on the substrate, and
forming an organic microlens made of an organic material above a pixel in which the inorganic microlens is not formed.

9. The manufacturing method of the solid-state imaging device according to claim 8,
wherein the process of forming the organic microlens includes
forming an organic microlens layer made of an organic material above a given pixel by patterning and
deforming the organic microlens layer by thermal reflow.

10. The manufacturing method of the solid-state imaging device according to claim 9,
wherein the inorganic microlenses are formed in a checkered pattern.

11. The manufacturing method of the solid-state imaging device according to claim 10, further comprising:
forming a planarization film made of an organic material on the substrate, and
forming a stress relaxation layer at least one layer or more on the planarization film before the process of forming the inorganic microlens.

12. The manufacturing method of the solid-state imaging device according to claim 11,
wherein the inorganic microlens is made of any of Si₃N₄, SiO₂ and SiON (0<X≦1, 0<Y≦1).

13. The manufacturing method of the solid-state imaging device according to claim 12,
wherein the stress relaxation layer is made of at least one or more materials selected from silicon compounds represented by Si₃N₄, SiO₂ and SiON (0<X≦1, 0<Y≦1).

14. The manufacturing method of the solid-state imaging device according to claim 13,
wherein a refractive index of the stress relaxation layer is 1.4 to 2.0.

15. The manufacturing method of the solid-state imaging device according to claim 8,
wherein organic microlenses having different refractive indexes are formed by repeating the formation of the organic microlenses.

16. An electronic apparatus comprising:
an optical lens;
a solid-state imaging device having
a substrate on which plural pixels having photoelectric converters are formed,
an inorganic microlens made of an inorganic material and formed above the substrate, and
an organic microlens made of an organic material and formed adjacent to the inorganic microlens so that a hem portion touches or overlaps a hem portion of the inorganic microlens, on which light condensed on the optical lens is incident; and
a signal processing circuit processing output signals outputted from the solid-state imaging device.
